(19) United States
(12) Patent Application Publication
(10) Pub. No.: US 2010/0124128 A1
(43) Pub. Date: May 20, 2010

(54) NAND FLASH MEMORY

(75) Inventors: Osamu NAGAO, Yokohama-Shi (JP); Yoshihisa Watanabe, Yokohama-Shi (JP); Koichi Fukuda, Yokohama-Shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/556,219

(22) Filed: Sep. 9, 2009

(30) Foreign Application Priority Data
Nov. 20, 2008 (JP) 2008-296841

(51) Int. Cl. G11C 16/16; G11C 16/04

(52) U.S. Cl. 365/185.33; 365/185.11

(57) ABSTRACT

A NAND flash memory in which data is erased in blocks, has a plurality of memory cell transistors provided in each of the blocks, the memory cell transistor having a floating gate which is formed via a first gate insulating film on a well formed on a semiconductor substrate and a control gate which is formed on the floating gate via a second gate insulating film, and being capable of rewriting data by controlling an amount of charge accumulated on the floating gate; and a row decoder having a plurality of n-type transfer MOS transistors having drains respectively connected to word lines respectively connected to the control gates of the plurality of memory cell transistors, the row decoder controlling gate voltages and source voltages of the transfer MOS transistors.

### CROSS-REFERENCE TO RELATED APPLICATION

This application is based upon and claims the benefit of priority from the prior Japanese Patent Application No. 2008-296841, filed on Nov. 20, 2008, the entire contents of which are incorporated herein by reference.

### BACKGROUND OF THE INVENTION

1. Field of the Invention

The present invention relates to a NAND flash memory in which writing and erasure are performed on memory cell transistors.

2. Background Art

In a NAND flash memory of the prior art, data is erased in blocks, that is, simultaneously in all memory cell transistors in a selected block. In other words, in an unselected block, data should not be erased in all memory cell transistors (for example, see Japanese Patent Laid-Open No. 2005-243211).

When data is erased in the NAND flash memory, a boosted erasing voltage (e.g., about 20 V) is applied to the wells of memory cell transistors.

Further, 0 V (ground voltage) is applied to all word lines WL in a selected block.

On the other hand, all word lines WL in an unselected block are controlled to a floating state. Thus when the erasing voltage (about 20 V) is applied to the wells, a voltage as high as the boosted erasing voltage (20 V) is applied by coupling to all the word lines WL of the unselected block.

In this case, the word lines WL are connected to the drain sides of the transfer MOS transistors of a row decoder.

In the erasing operation, the transfer MOS transistors connected to the word lines WL of the selected block are turned on and the source voltages of the transistors are controlled to 0 V. The transfer MOS transistors connected to the unselected word lines WL are turned off (the gate voltages are 0 V) and the source voltages of the transistors are controlled to 0 V.

Thus when the erasing voltage is applied to the wells, 20 V is applied to the drains, 0 V is applied to the gates, and 0 V is applied to the sources of the transfer MOS transistors connected to the word lines WL of the unselected block. Therefore, when data is erased, the word lines WL where data is not erased in the unselected block are in a floating state.

For example, when data is erased in the prior art, the source sides of the transfer MOS transistors are all controlled to 0 V (ground voltage), the gate voltages of transfer MOS transistors of a selected block are controlled to 2 V to 3 V, and the gate voltages of transfer MOS transistors of an unselected block are controlled to 0 V (ground voltage).

Thus the voltages of the word lines WL of the selected block are controlled to 0 V (ground voltage) and the word lines WL of the unselected block are in a floating state (voltages increase with a substrate).

When data is erased, the transfer MOS transistors of the unselected block are controlled to be cut off. Thus the gate and source of the transfer MOS transistor have the same voltage and the drain of the transfer MOS transistor has a higher voltage, so that leak current is likely to occur between the drain and source of the transfer MOS transistor.

The passage of leak current reduces the voltage of the word line WL, thereby increasing a potential difference between the substrate and the word line WL. Thus electrons accumulated on the floating gate of the memory cell transistor are drawn to the substrate.

In other words, in the prior art, data stored in memory cell transistors may be erroneously erased in an unselected block when data is erased in a NAND flash memory.

### SUMMARY OF THE INVENTION

According to one aspect of the present invention, there is provided: a NAND flash memory in which data is erased in blocks, comprising:

a plurality of memory cell transistors provided in each of the blocks, the memory cell transistor having a floating gate which is formed via a first gate insulating film on a well formed on a semiconductor substrate and a control gate which is formed on the floating gate via a second gate insulating film, and being capable of rewriting data by controlling an amount of charge accumulated on the floating gate; and

a row decoder having a plurality of n-type transfer MOS transistors having drains respectively connected to word lines respectively connected to the control gates of the plurality of memory cell transistors, the row decoder controlling gate voltages and source voltages of the transfer MOS transistors,

wherein when data is erased,

a first gate voltage for turning on a first transfer MOS transistor of the transfer MOS transistors is applied to a gate of the first transfer MOS transistor and a control voltage is applied to a source of the first transfer MOS transistor in a state in which a substrate voltage of the first transfer MOS transistor is kept at a ground voltage, the first transfer MOS transistor being connected to the memory cell transistor of a selected block, and

a second gate voltage for turning off a second transfer MOS transistor of the transfer MOS transistors is applied to a gate of the second transfer MOS transistor and the control voltage is applied to a source of the second transfer MOS transistor in a state in which a substrate voltage of the second transfer MOS transistor is kept at the ground voltage, the second transfer MOS transistor being connected to the memory cell transistor of an unselected block, and

then data stored in the memory cell transistors of the selected block is erased by applying an erasing voltage higher than the control voltage to the well.

### BRIEF DESCRIPTION OF THE DRAWINGS

FIG. 1 is a block diagram showing an example of the configuration of a NAND flash memory 100 according to a first embodiment which is an aspect of the present invention;

FIG. 2 is a circuit diagram showing a configuration including the memory cell array 1 and the row decoder 6 of FIG. 1;

FIG. 3 is a sectional view showing the memory cell transistor M of the memory cell array 1 shown in FIG. 2;

FIG. 4 is a sectional view showing the selecting gate transistors S1 and S2 of the memory cell array 1 shown in FIG. 2;

FIG. 5 is a waveform chart showing an operation for applying the erasing voltage to the well for the certain period when data is erased in the NAND flash memory 100;

FIG. 6 is an explanatory drawing showing a state of the erasing operation of the memory cell transistor M in a selected block of the NAND flash memory 100 according to the first embodiment;

FIG. 7 is an explanatory drawing showing a state of the erasing operation of the memory cell transistor M in an unselected block of the NAND flash memory 100 according to the first embodiment;

FIG. 8 is an explanatory drawing showing a state of the erasing operation of a memory cell transistor M in a selected block of a NAND flash memory according to the prior art;

FIG. 9 is an explanatory drawing showing a state of the erasing operation of the memory cell transistor M in an unselected block of the NAND flash memory according to the prior art;

FIG. 10 is a figure showing the relationship between the voltage of the word line of the unselected block and an erasing time when data is erased according to the first embodiment;

FIG. 11 is figure showing a state of the transfer MOS transistors connected to the memory cell transistors of the selected block in the NAND flash memory 100;

FIG. 12 is a figure showing a state of the transfer MOS transistors connected to the memory cell transistors of the unselected block of the NAND flash memory 100; and

FIG. 13 is a flowchart showing an example of the flow of an erasing operation in the NAND flash memory 100 according to the first embodiment.

### DETAILED DESCRIPTION

The following will describe embodiments of the present invention in accordance with the accompanying drawings.

### First Embodiment

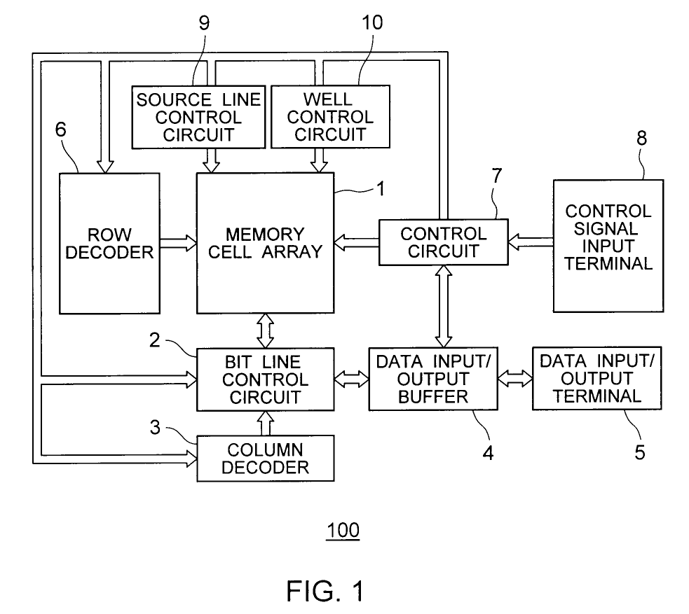

FIG. 1 is a block diagram showing an example of the configuration of a NAND flash memory 100 according to a first embodiment which is an aspect of the present invention.

As shown in FIG. 1, the NAND flash memory 100 includes a memory cell array 1, a bit line control circuit 2, a column decoder 3, a data input/output buffer 4, a data input/output terminal 5, a row decoder 6, a control circuit 7, a control signal input terminal 8, a source line control circuit 9, and a well control circuit 10.

The memory cell array 1 includes a plurality of bit lines, a plurality of word lines, and a common source line. In the memory cell array 1, for example, memory cell transistors which are made up of EEPROM cells and capable of electrically rewriting data are arranged in a matrix.

To the memory cell array 1, the bit line control circuit 2 for controlling the voltages of the bit lines and the row decoder 6 for controlling the voltages of the word lines are connected. The plurality of memory cell transistors are arranged in a plurality of blocks. When data is erased, one of the blocks is selected by the row decoder 6 and the other blocks are unselected.

The bit line control circuit 2 includes a sense amplifier (not shown) for sense-amplifying the voltages of the bit lines in the memory cell array 1 and a data storage circuit (not shown) acting as a data latch circuit for latching data for writing.

The bit line control circuit 2 reads the data of the memory cell transistors in the memory cell array 1 through the bit lines, detects the states of the memory cell transistors through the bit lines, and applies a writing control voltage to the memory cell transistors through the bit lines to perform writing on the memory cell transistors.

Further, to the bit line control circuit 2, the column decoder 3 and the data input/output buffer 4 are connected. The data storage circuit in the bit line control circuit 2 is selected by the column decoder 3, and data read from the memory cell transistors to the data storage circuit is outputted from the data input/output terminal 5 to the outside through the data input/output buffer 4.

Moreover, written data inputted to the data input/output terminal 5 from the outside is stored in the data storage circuit selected by the column decoder 3, through the data input/output buffer 4.

The row decoder 6 is connected to the memory cell array 1. The row decoder 6 applies a voltage for reading, writing, or erasing to the word lines of the memory cell array 1.

The source line control circuit 9 is connected to the memory cell array 1. The source line control circuit 9 controls the voltage of the source line.

The well control circuit 10 is connected to the memory cell array 1. The well control circuit 10 controls the voltage of a semiconductor substrate (well) on which the memory cell transistors are formed.

The control circuit 7 controls the memory cell array 1, the bit line control circuit 2, the column decoder 3, the data input/output buffer 4, the row decoder 6, the source line control circuit 9, and the well control circuit 10.

In this configuration, the control circuit 7 includes a voltage boosting circuit (not shown) for boosting a power supply voltage. The control circuit 7 boosts the power supply voltage by means of the voltage boosting circuit when necessary, and supplies the power supply voltage to the bit line control circuit 2, the column decoder 3, the data input/output buffer 4, the row decoder 6, the source line control circuit 9, and the well control circuit 10.

The control circuit 7 performs control in response to a control signal inputted from the outside through the control signal input terminal 8. In other words, the control circuit 7 generates desired voltages during data programming, verification, reading, and erasure in response to the control signal and supplies the voltages to the parts of the memory cell array 1.

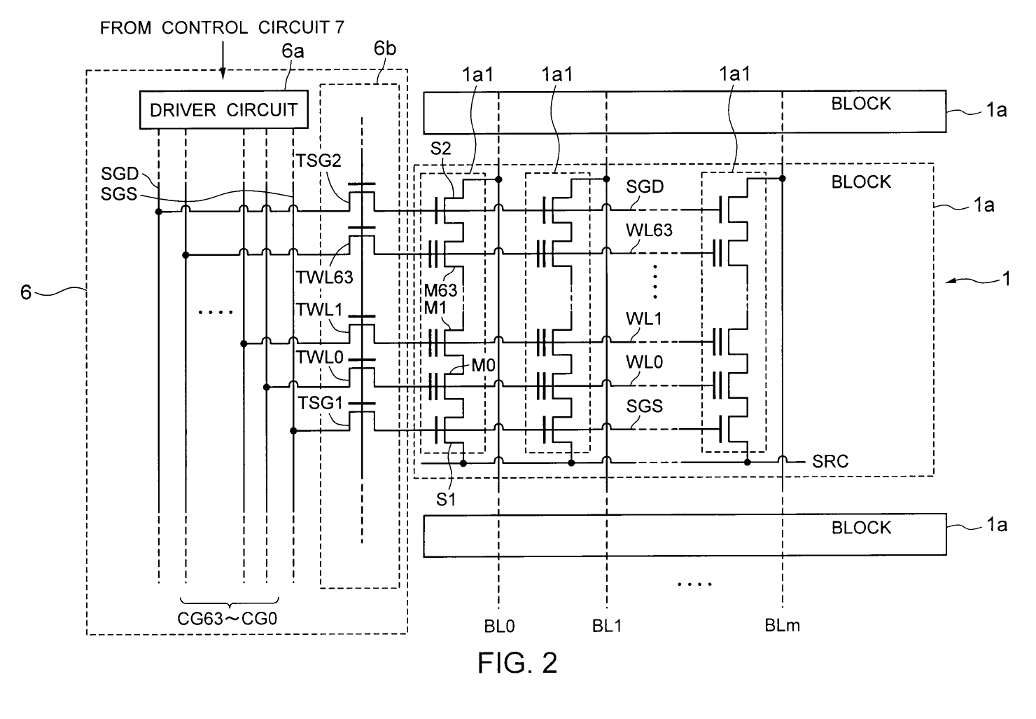

FIG. 2 is a circuit diagram showing a configuration including the memory cell array 1 and the row decoder 6 of FIG. 1.

As described above, the memory cell array 1 has blocks 1a, each including a plurality of NAND cell units 1a1 connected as shown in FIG. 2.

The NAND cell units 1a1 are each made up of, for example, 64 memory cell transistors M0, M1, . . . , and M63 connected in series, a selecting gate transistor S1 connected to the memory cell transistor M0, and a selecting gate transistor S2 connected to the memory cell transistor M63.

In other words, the memory cell transistors M0, M1, . . . , and M63 are provided in each block.

The first selecting gate transistor S1 is connected to a bit line BL0. The second selecting gate transistor S2 is connected to a source line SRC.

The control gates of the memory cell transistors M0, M1, . . . , and M63 disposed in each row are connected to word lines WL0, WL1, . . . , and WL63.

In the following explanation, the word lines WL0, WL1, and WL63 may be simply referred to as word lines WL for the sake of simplicity.

The gate of the first selecting gate transistor S1 is connected in common to a select line SGS. The gate of the second selecting gate transistor S2 is connected in common to a select line SGD.

Further, as shown in FIG. 2, the row decoder 6 has a driver circuit 6a and a transfer circuit 6b.

The transfer circuit 6b corresponds to each of the blocks 1a and includes a plurality of transfer MOS transistor TSG1, TSG2, TWL0 to TWL63 which are n-type MOS transistors.

The drains of the transfer MOS transistors TSG1 and TSG2 are respectively connected to the select lines SGS and SGD which are connected to the control gates of the selecting gate transistors S1 and S2.

The sources of the transfer MOS transistors TSG1 and TSG2 are respectively connected to the select lines SGS and SGD which are connected to the driver circuit 6a.

The drains of the transfer MOS transistors TWL0 to TWL63 are respectively connected to the word lines WL0 to WL63 which are connected to the control gates of the memory cell transistors M0 to M63.

The sources of the transfer MOS transistors TWL0 to TWL63 are respectively connected to control lines CG0 to CG63 which are connected to the driver circuit 6a.

In the following explanation, the control lines CG0 to CG63 may be simply referred to as control lines CG for the sake of simplicity.

The driver circuit 6a controls the gate voltages and the source voltages of the MOS transistors TSG1, TSG2, and TWL0 to TWL63 according to the output of the control circuit 7.

In other words, the row decoder 6 controls the plurality of MOS transistors TSG1, TSG2, and TWL0 to TWL63 by controlling the gate voltages and the source voltages with the driver circuit 6a, and selects the block 1a of the memory cell array 1.

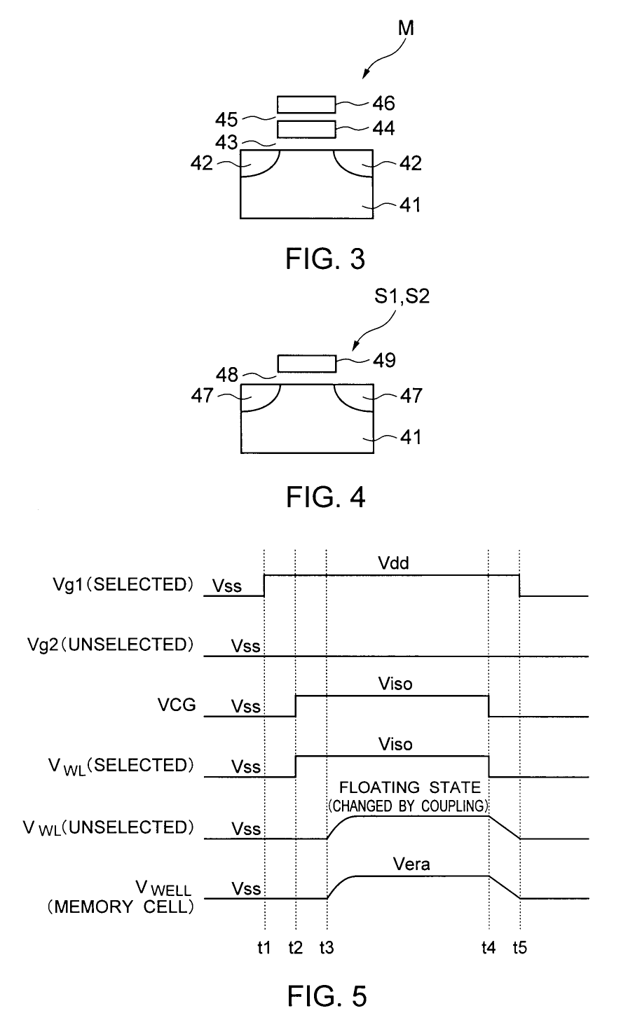

FIG. 3 is a sectional view showing the memory cell transistor M of the memory cell array 1 shown in FIG. 2. In the following explanation, the memory cell transistor M corresponds to one of the memory cell transistors M0 to M63 shown in FIG. 2.

As shown in FIG. 3, the memory cell transistor M has a floating gate 44, a control gate 46, and a diffusion layer 42.

The diffusion layer 42 serving as the source/drain regions of the memory cell transistor M is formed on a well (hereinafter, will be also simply referred to as a semiconductor substrate) 41 formed on the semiconductor substrate. On the well 41, the floating gate 44 is formed via a gate insulating film (tunnel insulating film) 43. On the floating gate 44, the control gate 46 is formed via a gate insulating film 45.

The memory cell transistor M stores data according to a threshold voltage. The threshold voltage is determined by an amount of charge accumulated in the floating gate 44. The amount of charge in the floating gate 44 can be changed by a tunnel current passing through the gate insulating film 43.

In other words, when the control gate 46 has a sufficiently high voltage relative to the well 41 and the diffusion layer (source/drain regions) 42, electrons are injected to the floating gate 44 through the gate insulating film 43. Thus the threshold voltage of the memory cell transistor M is increased.

On the other hand, when the well 41 and the diffusion layer (source/drain regions) 42 have sufficiently high voltages relative to the control gate 46, electrons are emitted from the floating gate 44 through the gate insulating film 43. Thus the threshold voltage of the memory cell transistor M is reduced.

As described above, the memory cell transistor M can rewrite stored data by controlling an amount of charge accumulated in the floating gate 44.

FIG. 4 is a sectional view showing the selecting gate transistors S1 and S2 of the memory cell array 1 shown in FIG. 2.

As shown in FIG. 4, on the well 41, a diffusion layer 47 serving as the source/drain regions of the selecting gate transistors S1 and S2 is formed. Further, on the well 41, a control gate 49 is formed via a gate insulating film 48.

The well (substrate) on which the selecting gate transistors S1 and S2 and the memory cell transistors M are formed and the well (substrate) on which the transfer MOS transistors TSG1, TSG2, and TWL0 to TWL63 (FIG. 2) are formed are isolated from each other by STI and the like.

Hence, it is possible to separately control the substrate (well) voltage of the selecting gate transistors S1 and S2 and the memory cell transistor M and the substrate (well) voltage of the transfer MOS transistors TSG1, TSG2, and TWL0 to TWL63.

The following will describe the operation of the NAND flash memory 100 configured thus.

In the NAND flash memory 100, data is erased in blocks, that is, simultaneously in all the memory cell transistors in a selected block.

The following will describe an example of an operation sequence for applying an erasing voltage Vera to the well for a certain period when data is erased in the NAND flash memory 100.

FIG. 5 is a waveform chart showing an operation for applying the erasing voltage to the well for the certain period when data is erased in the NAND flash memory 100.

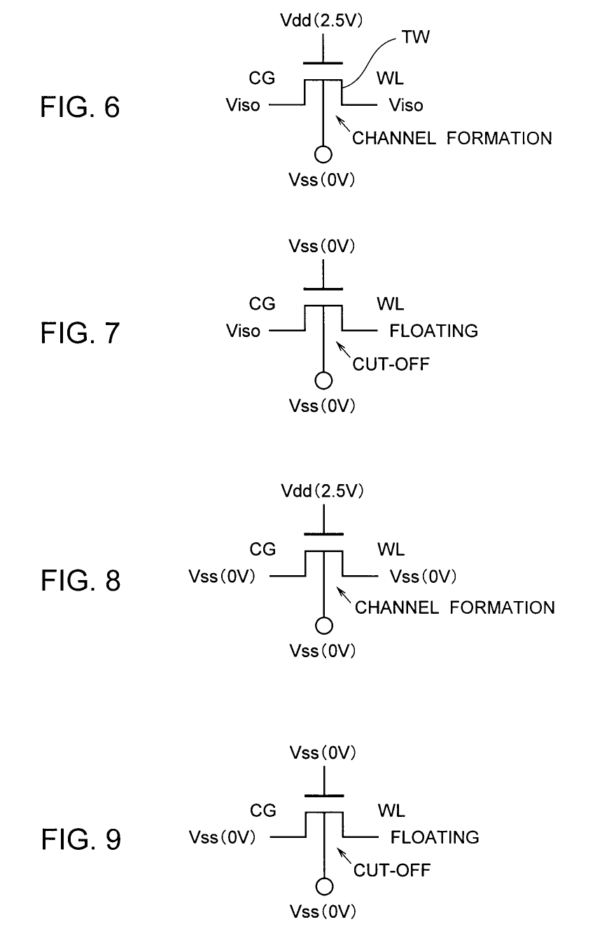

FIG. 6 is an explanatory drawing showing a state of the erasing operation of the memory cell transistor M in a selected block of the NAND flash memory 100 according to the first embodiment. FIG. 7 is an explanatory drawing showing a state of the erasing operation of the memory cell transistor M in an unselected block of the NAND flash memory 100 according to the first embodiment.

FIG. 8 is an explanatory drawing showing a state of the erasing operation of a memory cell transistor M in a selected block of a NAND flash memory according to the prior art. FIG. 9 is an explanatory drawing showing a state of the erasing operation of the memory cell transistor M in an unselected block of the NAND flash memory according to the prior art.

In FIG. 5, as an initial state, of the transfer MOS transistors of the transfer circuit 6b, the substrate voltage of the first transfer MOS transistor connected to the memory cell transistor of the selected block is kept at a ground voltage Vss (0 V). Further, of the transfer MOS transistors of the transfer circuit 6b, the substrate voltage of the second transfer MOS transistor connected to the memory cell transistor of the unselected block is kept at the ground voltage Vss (0 V).

In this state, a first gate voltage Vg1, a second gate voltage Vg2, a voltage VCG of the control line CG, a well voltage VWELL (memory cell) of the memory cell transistor are set at the ground voltage Vss (0 V). In this case, the first gate voltage Vg1 is a voltage applied to the gate of the first transfer MOS transistor connected to the memory cell transistor of the selected block. The second gate voltage Vg2 is a voltage applied to the gate of the second transfer MOS transistor connected to the memory cell transistor of the unselected block.

As shown in FIG. 5, at time t1, the row decoder 6 sets the first gate voltage Vg1 at a power supply voltage Vdd. In other words, from time t1 to time t5, the first gate voltage Vg1 is set at the power supply voltage Vdd.

Thus the first transfer MOS transistors connected to all the word lines WL of the selected block are turned on. At this point, the voltages of all the word lines WL of the selected block are set at the ground voltage Vss (0 V).

The row decoder 6 turns off the selecting gate transistors S1 and S2 of the selected block. In other words, all the select lines SGS and SGD of the selected block are controlled to a floating state.

Further, the row decoder 6 keeps the second gate voltage Vg2 at the ground voltage Vss (from time t1). In other words, from time t1 to time t5, the second gate voltage Vg2 is set at or above the ground voltage Vss and is set below a control voltage Viso. In this case, particularly, the second gate voltage Vg2 is set at the ground voltage Vss (0 V).

Thus the second transfer MOS transistors connected to all the word lines WL of the unselected block are kept turned off. In other words, all the word lines WL of the unselected block are controlled to a floating state. At this point, the source voltage of the second transfer MOS transistor is set at 0 V.

Moreover, the row decoder 6 turns off the selecting gate transistors S1 and S2 of the unselected block. In other words, all the select lines SGS and SGD of the unselected block are controlled to a floating state.

As described above, of the transfer MOS transistors, the substrate voltage of the first transfer MOS transistor connected to the memory cell transistor of the selected block is kept at the ground voltage Vss. In this state, the row decoder 6 applies the first gate voltage Vg1 (power supply voltage Vdd), which turns on the first MOS transistor, to the gate of the first transfer MOS transistor and applies the control voltage Viso to the source of the first transfer MOS transistor. Further, of the transfer MOS transistors, the substrate voltage of the second transfer MOS transistor connected to the memory cell transistor of the unselected block is kept at the ground voltage Vss. In this state, the row decoder 6 applies the second gate voltage Vg2 (ground voltage Vss), which turns off the second MOS transistor, to the gate of the second transfer MOS transistor and applies the control voltage Viso to the source of the second transfer MOS transistor.

Next, at time t2, the row decoder 6 sets the voltage VCG of the control line CG at the control voltage Viso. Since the first transfer MOS transistor is turned on, a voltage VWL (selected) of the word line WL connected to the first transfer MOS transistor in the selected block is increased from the ground voltage Vss to the control voltage Viso (FIG. 6).

After that, at time t3, the well control circuit 10 in this state applies the erasing voltage (e.g., about 20 V) Vera higher than the control voltage Viso to the well on which the memory cell transistors are formed.

When the erasing voltage Vera is applied to the well, a voltage as high as the boosted erasing voltage Vera is applied to all the word lines WL of the unselected block by coupling (from time t3 to time t4). In other words, as the voltage VWELL of the well increases, the voltages VWL (unselected) of all the word lines WL of the unselected block are increased. At this point, the select lines, the control lines, the bit lines, and the source line are also controlled to a voltage as high as the erasing voltage Vera by coupling and the like.

In other words, a predetermined potential difference by which data is erased does not occur between the floating gate of the memory cell transistor of the unselected block and the well (semiconductor substrate).

Thus electrons are not emitted to the well from the floating gate of the memory cell transistor of the unselected block and the threshold voltage is not changed. In other words, data stored in the memory cell transistors of the unselected block is not erroneously erased.

From time t3 to time t4, the voltages VWL (selected) of the word lines WL of the selected block are kept at the control voltage Viso. Thus the predetermined potential difference occurs between the floating gate and the well (semiconductor substrate). At this point, the select lines, the control lines, the bit lines, and the source line are also controlled by coupling and the like to about 20 V as high as the erasing voltage. In other words, the well (semiconductor substrate) and the diffusion layer (source and drain) have sufficiently high potentials relative to the control gates of the memory cell transistors of the selected block.

Hence, electrons are emitted from the floating gate of the memory cell transistor M of the selected block to the well through the tunnel insulating film, and the threshold voltage is shifted to the negative side. In other words, data stored in the memory cell transistors of the selected block is erased.

Next, the voltage VWELL (memory cell) applied to the well is reduced, so that the voltages VWL (unselected) of the word lines WL of the unselected block are also reduced (from time t4 to time t5).

At time t5, the row decoder 6 reduces the first gate voltage Vg1 from the power supply voltage to the ground voltage Vss.

One erasing operation of the NAND flash memory 100 is completed thus.

In the prior art, all the control lines CG are set at the ground voltage Vss (0 V) as shown in FIGS. 8 and 9.

In the present embodiment, as shown in FIG. 7, the voltage of the control line CG is set at the control voltage Viso. The control voltage Viso is lower than a voltage obtained by subtracting the threshold voltage of the first transfer MOS transistor from the first gate voltage Vg1 (in this case, the power supply voltage Vdd) and is higher than the ground voltage Vss. The control voltage Viso is set at, for example, 0.5 V to 1.0 V.

Thus it is possible to more reliably turn off the second transfer MOS transistor connected to the memory cell transistor of the unselected block. In other words, in the erasing operation, it is possible to suppress leak current passing through the second memory cell transistor.

Thus it is possible to suppress erroneous erasure on the memory cell transistors of the unselected block.

As shown in FIG. 6, in the selected block, the potential of the control line CG is Viso, so that the voltage of the word line WL is also set at the control voltage Viso. However, the control voltage Viso is limited to the above range and thus the transfer MOS transistor is not cut off. Moreover, by limiting the control voltage Viso to the above range, a potential difference between the word line WL and the substrate (well) does not considerably change.

Hence, even the above erasing operation hardly affects the erasing characteristics of the memory cell transistors in the NAND flash memory 100 according to the first embodiment.

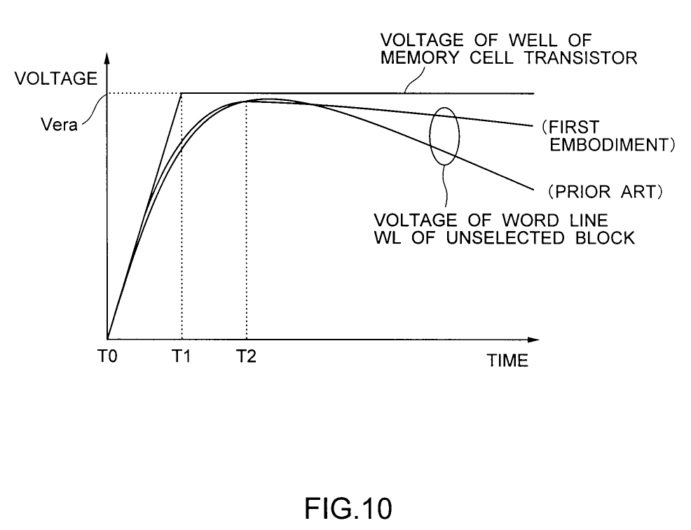

FIG. 10 shows the relationship between the voltage of the word line of the unselected block and an erasing time when data is erased according to the first embodiment. In FIG. 10, time T0 corresponds to time t3 of FIG. 5.

As shown in FIG. 10, the well control circuit 10 applies the boosted erasing voltage Vera, e.g., about 20 V to the well on which the memory cell transistors are formed (at time T1). Thus by coupling between the well and the control gates (word lines), the voltages of the word lines WL of the unselected block are increased to a voltage as high as the erasing voltage Vera (at time T2).

In the NAND flash memory of the prior art, the transfer MOS transistors are not sufficiently cut off, causing leak current.

When current continues to leak, the word lines of the unselected block have a voltage drop.

As described above, in the NAND flash memory of the prior art, erroneous erasure may occur in an unselected block.

In the NAND flash memory 100 of the present embodiment, as described above, the voltage of the control line CG is set at the control voltage Viso during an erasing operation. Thus the cut-off characteristics of the transfer MOS transistors of the unselected block are improved by a back bias effect.

Therefore, it is possible to reduce the leak current of the transfer MOS transistors. In other words, it is possible to suppress a reduction in the voltages of the word lines WL. The reduction in the voltages of the word lines WL results in erroneous erasure in the unselected block.

As described above, in the NAND flash memory 100 of the first embodiment, the cut-off characteristics of the transfer MOS transistors of the unselected block are improved when data is erased. Thus it is possible to suppress a reduction in the voltages of the word lines of the unselected block.

In other words, in the NAND flash memory 100 of the first embodiment, erroneous erasure of data is suppressed in the unselected block.

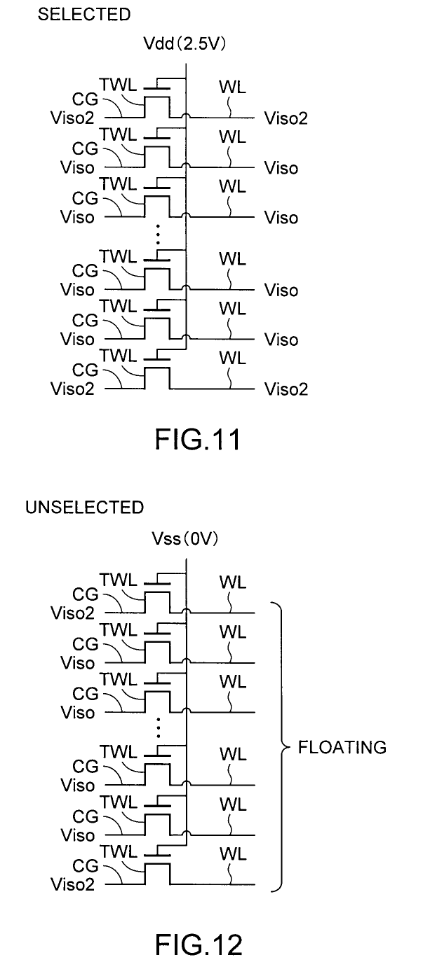

FIG. 11 shows a state of the transfer MOS transistors connected to the memory cell transistors of the selected block in the NAND flash memory 100. FIG. 12 shows a state of the transfer MOS transistors connected to the memory cell transistors of the unselected block of the NAND flash memory 100.

As shown in FIGS. 11 and 12, a control voltage Viso2 applied to specific one of the control lines CG may be different from the control voltage Viso applied to the other control lines CG. The relationship between the control voltages Viso and Viso2 is set, for example, such that the memory cell transistors have uniform erasing characteristics in the selected block during an erasing operation.

Thus the memory cell transistors in a block can have uniform erasing characteristics.

The control voltage Viso may be changed every time data is erased in the NAND flash memory. The following will describe an example of a flow when the control voltage of the NAND flash memory 100 may be changed in each erasing operation.

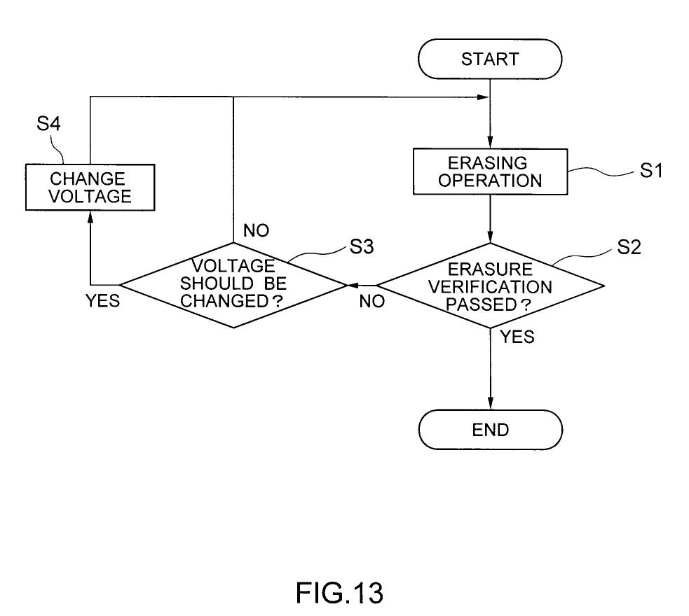

FIG. 13 is a flowchart showing an example of the flow of an erasing operation in the NAND flash memory 100 according to the first embodiment.

As shown in FIG. 13, first, the control circuit 7 performs an erasing operation for erasing data stored in the memory cell transistors of the selected block according to, for example, the sequence operation of FIG. 5 (step S1).

Next, the control circuit 7 verifies whether the threshold voltages of the memory cell transistors of the selected block are not higher than a threshold voltage corresponding to an erasing state (step S2).

In step S2, when the control circuit 7 verifies that the threshold voltages of the memory cell transistors of the selected block are not higher than the first threshold voltage, the flow of the erasing operation is completed.

In step S2, when the control circuit 7 verifies that the threshold voltages of the memory cell transistors of the selected block are higher than the threshold voltage corresponding to the erasing state, the control circuit 7 determines whether the control voltage Viso should be changed or not (step S3).

In step S3, when the control circuit 7 determined that the control voltage should not be changed, the process returns to step S1. After that, the same flow is carried out.

In step S3, when the control circuit 7 determined that the control voltage should be changed, the control circuit 7 changes the control voltage Viso (step S4). After that, the process returns to step S1.

The control voltage Viso may be changed thus every time data is erased. When erasure of data is not completed in one erasing operation, the control voltages Viso and Viso2 are changed after the erasing operation.

Thus the memory cell transistors can have uniform erasing characteristics regardless of the number of erasing operations.

As described above, according to the NAND flash memory of the present embodiment, it is possible to suppress erroneous erasure of data in an unselected block.

What is claimed is:

1. A NAND flash memory in which data is erased in blocks, comprising:
a plurality of memory cell transistors provided in each of the blocks, the memory cell transistor having a floating gate which is formed via a first gate insulating film on a well formed on a semiconductor substrate and a control gate which is formed on the floating gate via a second gate insulating film, and being capable of rewriting data by controlling an amount of charge accumulated on the floating gate; and
a row decoder having a plurality of n-type transfer MOS transistors having drains respectively connected to word lines respectively connected to the control gates of the plurality of memory cell transistors, the row decoder controlling gate voltages and source voltages of the transfer MOS transistors,
wherein when data is erased,
a first gate voltage for turning on a first transfer MOS transistor of the transfer MOS transistors is applied to a gate of the first transfer MOS transistor and a control voltage is applied to a source of the first transfer MOS transistor in a state in which a substrate voltage of the first transfer MOS transistor is kept at a ground voltage, the first transfer MOS transistor being connected to the memory cell transistor of a selected block, and
a second gate voltage for turning off a second transfer MOS transistor of the transfer MOS transistors is applied to a gate of the second transfer MOS transistor and the control voltage is applied to a source of the second transfer MOS transistor in a state in which a substrate voltage of the second transfer MOS transistor is kept at the ground voltage, the second transfer MOS transistor being connected to the memory cell transistor of an unselected block, and
then data stored in the memory cell transistors of the selected block is erased by applying an erasing voltage higher than the control voltage to the well.

2. The NAND flash memory according to claim 1, wherein the control voltage is lower than a voltage obtained by subtracting a threshold voltage of the first transfer MOS transistor from the first gate voltage and is higher than the ground voltage.

3. The NAND flash memory according to claim 1, wherein the first gate voltage is set at a power supply voltage.

4. The NAND flash memory according to claim 2, wherein the first gate voltage is set at a power supply voltage.

5. The NAND flash memory according to claim 1, wherein the second gate voltage is set at or above the ground voltage and is set below the control voltage.

6. The NAND flash memory according to claim 2, wherein the second gate voltage is set at or above the ground voltage and is set below the control voltage.

7. The NAND flash memory according to claim 3, wherein the second gate voltage is set at or above the ground voltage and is set below the control voltage.

8. The NAND flash memory according to claim 1, wherein the second gate voltage is set at the ground voltage.

9. The NAND flash memory according to claim 2, wherein the second gate voltage is set at the ground voltage.

10. The NAND flash memory according to claim 3, wherein the second gate voltage is set at the ground voltage.

11. The NAND flash memory according to claim 4, wherein the second gate voltage is set at the ground voltage.

12. The NAND flash memory according to claim 1, wherein the control voltage is changed every time data is erased.

13. The NAND flash memory according to claim 2, wherein the control voltage is changed every time data is erased.

14. The NAND flash memory according to claim 3, wherein the control voltage is changed every time data is erased.

15. The NAND flash memory according to claim 4, wherein the control voltage is changed every time data is erased.

16. The NAND flash memory according to claim 5, wherein the control voltage is changed every time data is erased.

17. The NAND flash memory according to claim 6, wherein the control voltage is changed every time data is erased.

18. The NAND flash memory according to claim 7, wherein the control voltage is changed every time data is erased.

19. The NAND flash memory according to claim 8, wherein the control voltage is changed every time data is erased.

20. The NAND flash memory according to claim 9, wherein the control voltage is changed every time data is erased.
